(19) United States
(12) Patent Application Publication
(10) Pub. No.: US 2019/0275565 A1
(43) Pub. Date: Sep. 12, 2019

(54) METHOD OF SELECTIVELY REMOVING A CONTAMINANT FROM AN OPTICAL COMPONENT

(71) Applicant: GM Global Technology Operations LLC, Detroit, MI (US)

(72) Inventors: Ming Yang, Novi, MI (US); Mahmoud Abd Elhamid, Troy, MI (US); Qinglin Zhang, Novi, MI (US)

(73) Assignee: GM Global Technology Operations LLC, Detroit, MI (US)

(21) Appl. No.: 15/912,802

(22) Filed: Mar. 6, 2018

(51) Int. Cl. B08B 3/08; B08B 7/00; G02B 27/00; C30B 29/30; H01J 37/32

(52) U.S. Cl. CPC B08B 3/08; B08B 7/0042; H01J 2237/335; C30B 29/30; H01J 37/32; G02B 27/0006

(57) ABSTRACT

A method of selectively removing a contaminant from an optical component formed from lithium tantalate includes washing the optical component with a washing solution that includes a hard anion. The contaminant includes a hard cation. The method also includes forming a compound including the hard anion and the hard cation and rinsing the compound from the lithium tantalate to thereby selectively remove the contaminant from the optical component.

### INTRODUCTION

The disclosure relates to a method of selectively removing a contaminant from an optical component formed from lithium tantalate.

Optical components, such as mirrors, lenses, and resonators, are useful for light detection and ranging (LIDAR) applications that use light in the form of a pulsed laser to measure distances. More specifically, LIDAR technology allows for remote sensing and measurement and may therefore be incorporated into a wide range of devices including aircraft, farming equipment, earth-moving vehicles, and autonomous and semi-autonomous automotive vehicles. As such, demand for LIDAR devices and optical components with improved resolution continues to grow.

### SUMMARY

A method of selectively removing a contaminant from an optical component formed from lithium tantalate includes washing the optical component with a washing solution. The washing solution includes a hard anion and the contaminant includes a hard cation. The method also includes forming a compound including the hard anion and the hard cation, and rinsing the compound from the lithium tantalate to thereby selectively remove the contaminant from the optical component.

In one aspect, washing may include contacting the contaminant with the washing solution for from 5 minutes to 48 hours at a temperature of from 0 Kelvin to 493 Kelvin.

The method may further include contacting the contaminant with an oxidizer. The washing solution may be acidic and may have an acid concentration of from 0.01 mol/L to 5 mol/L. The method may further include sparging a gas through the washing solution.

In another aspect, the contaminant may be lithium niobate and the washing solution may include an acid selected from the group consisting of hydrofluoric acid, hydrochloric acid, acetic acid, nitric acid, sulfuric acid, phosphoric acid, and combinations thereof.

In yet another aspect, the washing solution may include hydrofluoric acid and the method may further comprise combining the washing solution and ammonium fluoride.

In a further aspect, the method may include contacting the contaminant with an oxidizer, and the washing solution may be basic and have an acid concentration of from 0.01 mol/L to 10 mol/L. The contaminant may be lithium niobate and the washing solution may include a base selected from the group consisting of ammonia, oxalate salts, and combinations thereof.

In another aspect, the washing solution may be selected from the group consisting of hydrazine, alcohols, ethers, amines, and combinations thereof.

The method may further include, prior to washing, attaching a mask to the optical component to cover an edge surface of the lithium tantalate and expose at least a portion of the contaminant. The washing solution may include hydrochloric acid and the method may further include dissolving the contaminant without dissolving the lithium tantalate. The method may further include, prior to washing, determining a dissolution rate of the contaminant at a plurality of temperatures.

In an additional aspect, the optical component may be arranged as an elongated sheet and the contaminant may be shaped as a flat surface. The method may further include discharging the washing solution from at least one sprinkler component disposed adjacent and facing the flat surface, and, after discharging, collecting the contaminant in a leachate reservoir connected to the at least one sprinkler component by a recirculation pump.

In another aspect, the optical component may be arranged as a plurality of chips, and the method may further include submerging the plurality of chips in the washing solution within a cavity defined by a batch reactor and sparging a fluid through the washing solution within the cavity. After submerging, the method may include suspending the contaminant in the washing solution and precipitating the lithium tantalate away from the contaminant within the cavity.

In another embodiment, a method of selectively removing a contaminant from an optical component formed from lithium tantalate includes maintaining a thickness of the lithium tantalate and physically separating the contaminant from the lithium tantalate to thereby selectively remove the contaminant from the optical component.

In one aspect, the optical component may be arranged as an elongated sheet and the contaminant may be shaped as a flat surface. Physically separating may include at least one of monatomic ion beam sputtering and gas cluster ion beam sputtering an inert target material at the contaminant.

In another aspect, physically separating may include exposing the optical component to a vacuum and plasma cleaning the contaminant from the lithium tantalate.

In a yet another aspect, physically separating may include melting the contaminant without melting the lithium tantalate.

In a further aspect, physically separating may include depositing an agglomerated suspension onto the contaminant and polishing the contaminant off the lithium tantalate with a polishing cloth. Further, maintaining may include not disturbing the lithium tantalate.

In an additional aspect, physically separating may include laser ablating the contaminant to evaporate the contaminant off the lithium tantalate, and maintaining may include not disturbing the lithium tantalate.

### BRIEF DESCRIPTION OF THE DRAWINGS

FIG. 1 is a flowchart of a method of selectively removing a contaminant from an optical component formed from lithium tantalate.

FIG. 2 is a flowchart of additional aspects of the method of FIG. 1.

FIG. 3 is a flowchart of further aspects of the method of FIGS. 1 and 2.

FIG. 4 is a flowchart of additional aspects of the method of FIGS. 1-3.

FIG. 5 is a schematic illustration of a side cross-sectional view of a mask disposed on an optical component and a portion of the method of FIG. 1.

FIG. 6 is a schematic illustration of a side view of another portion of the method of FIG. 1.

FIG. 7 is a schematic illustration of a side view of another embodiment of the portion of FIG. 6.

FIG. 8 is a schematic flowchart of another embodiment of the method of selectively removing a contaminant from an optical component formed from lithium tantalate.

FIG. 9 is a schematic illustration of a cross-sectional side view of a first embodiment of a portion of the method of FIG. 8.

FIG. 10 is a schematic illustration of a cross-sectional side view of a second embodiment of the portion of the method of FIG. 8.

FIG. 11 is a schematic illustration of a cross-sectional side view of a third embodiment of the portion of the method of FIG. 8.

FIG. 12 is a schematic illustration of a cross-sectional side view of a fourth embodiment of the portion of the method of FIG. 8.

FIG. 13 is a schematic illustration of a cross-sectional perspective view of a fifth embodiment of the portion of the method of FIG. 8.

FIG. 14 is a schematic illustration of a cross-sectional side view of a sixth embodiment of the portion of the method of FIG. 8.

### DETAILED DESCRIPTION

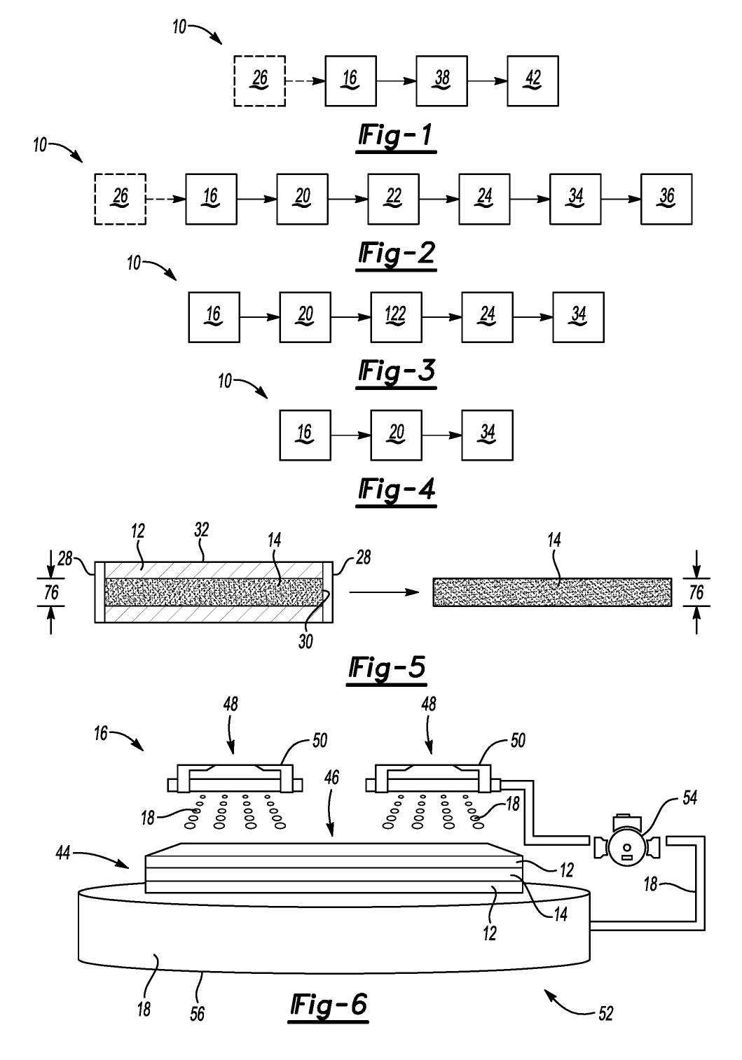

Referring to the Figures, wherein like reference numerals refer to like elements, a method 10 of selectively removing a contaminant 12 (FIG. 5) from an optical component 14 (FIG. 5) formed from lithium tantalate is shown generally in FIG. 1. In particular, the method 10 may be useful for applications and components that include light detection and ranging (LIDAR) technology. That is, the method 10 may be useful for removing contaminants 12 from optical components for LIDAR systems which use light in the form of a pulsed laser to measure distances. As such, the method 10 and resulting optical components 14 may be useful for vehicular applications such as, but not limited to, automobiles, airplanes, trains, trams, farming equipment, and boats. Alternatively, the method 10 and resulting optical components 14 may be useful for non-vehicular applications such as microscopes, drones, and the like. More specifically, by way of a non-limiting example, the method 10 and resulting optical components 14 may be useful for LIDAR applications for autonomous or semi-autonomous vehicle applications in which the user does not steer or control the motive power of the vehicle.

As described in further detail below, the method 10 selectively removes the contaminant 12 from the optical component 14. That is, the method 10 may remove only the contaminant 12 from the optical component 14 and may not remove any lithium tantalate, i.e., may leave the optical component 14 formed from the lithium tantalate intact. In particular, the contaminant 12 may be characterized as a nonmetallic residue or coating that is disposed on the optical component 14 during manufacturing of the optical component 14. The lithium tantalate may be characterized as a functional core material of the optical component 14, and the lithium niobate may be characterized as a sacrificial surface material. For example, the optical component 14 may be a resonator for a LIDAR device and may be formed from lithium tantalate, and the contaminant 12 may be lithium niobate. Without the method 10, the lithium niobate may be otherwise difficult to remove or separate from the optical component 14.

Chemical Separation of the Contaminant 12 from the Optical Component 14

The method 10 may include chemically separating the contaminant 12 from the optical component 14, as set forth in more detail below.

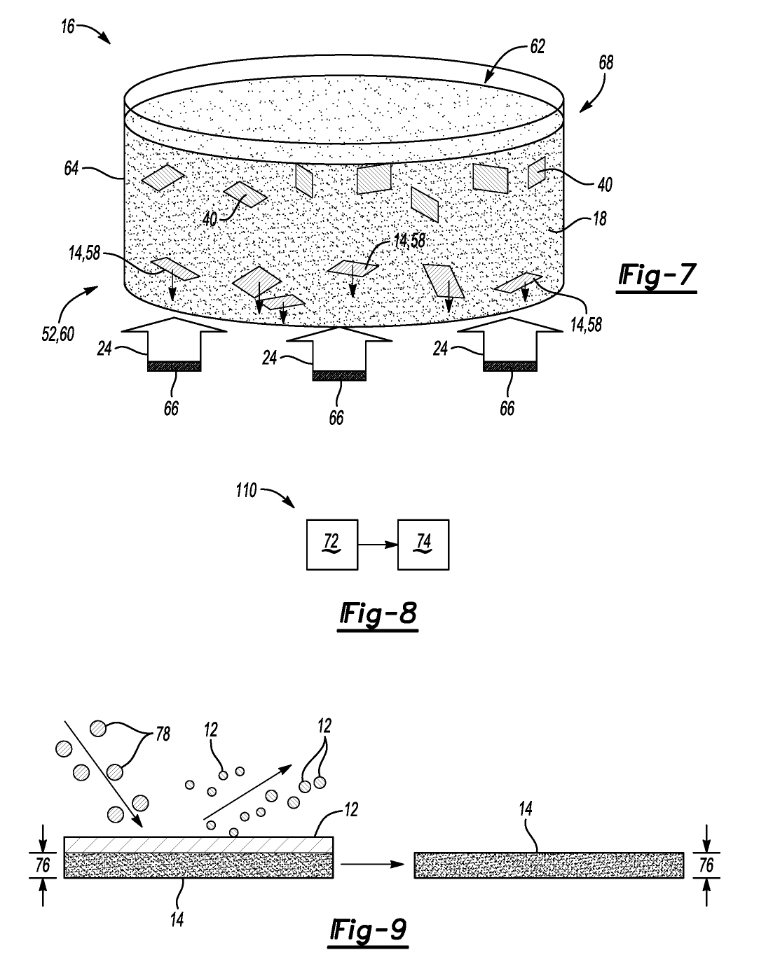

Referring to FIGS. 1, 6, and 7, the method 10 includes washing 16 the optical component 14 with a washing solution 18 (FIGS. 6 and 7) that includes a hard anion. That is, the washing solution 18 includes at least one hard anion, but may include a plurality or combination of hard anions. As used herein, the terminology hard anion refers to a negatively charged ion that, as compared to soft anions, has a comparatively high electronegativity (for bases), a comparatively low polarizability, a comparatively high oxidation state, a comparatively small atomic radius, and generally forms ionic bonds. Suitable examples of hard anions may include carbonate, sulfate, phosphate, carboxylate, nitrate, alcohol, halogens such as F⁻ and Cl⁻, amine, ammonia, hydroxide, ether, and oxalate. By comparison, suitable examples of soft anions may include hydride, thiolate, halogens such as I⁻, phosphine, thiocyanate, carbon monoxide, and benzene. In general, hard anions may form comparatively stronger bonds with hard cations, and soft anions may form comparatively stronger bonds with soft cations, as set forth in more detail below.

As set forth above, in one example, the contaminant 12 may be lithium niobate and includes a hard cation. As used herein, the terminology hard cation refers to a positively charged ion that, as compared to soft cations, has a comparatively low electronegativity (for bases), a comparatively high polarizability, a comparatively low oxidation state, a comparatively large atomic radius, and generally forms ionic bonds. Suitable examples of hard cations may include hydronium, alkali metals such as Li⁺, Na⁺, and K⁺, titanium, chromium, boron trifluoride, and lanthanides. By comparison, suitable examples of soft cations may include mercury, platinum, palladium, silver, borane, and gold. In general, hard cations may form comparatively stronger bonds with hard anions, and soft cations may form comparatively stronger bonds with soft anions.

Referring again to the method 10, washing 16 may include contacting the contaminant 12 with the washing solution 18 for from 5 minutes to 48 hours at a temperature of from 0 Kelvin to 493 Kelvin. For example, washing 16 may include contacting the contaminant 12 with the washing solution 18 for from 10 minutes or 20 minutes or 30 minutes or 40 minutes or 50 minutes or 1 hour or 1.5 hours or 2 hours or 2.5 hours or 3 hours or 3.5 hours or 4 hours or 4.5 hours or 5 hours or 6 hours or 7 hours or 8 hours or 9 hours or 10 hours or 12 hours or 14 hours or 16 hours or 18 hours or 20 hours or 22 hours or 24 hours or 28 hours or 32 hours or 36 hours or 40 hours or 41 hours or 42 hours or 43 hours or 44 hours or 45 hours or 46 hours or 47 hours or 48 hours at a temperature of from 10 Kelvin or 20 Kelvin or 30 Kelvin or 40 Kelvin or 50 Kelvin or 75 Kelvin or 100 Kelvin or 125 Kelvin or 150 Kelvin or 200 Kelvin or 250 Kelvin or 300 Kelvin or 350 Kelvin or 375 Kelvin or 400 Kelvin or 410 Kelvin or 420 Kelvin or 430 Kelvin or 440 Kelvin or 450 Kelvin or 460 Kelvin or 470 Kelvin or 480 Kelvin or 490 Kelvin.

Further, the washing solution 18 may be selected according to compatibility with liquid or gas phase leaching equipment. In one example best shown in FIG. 6, washing 16 may occur in a recirculating sprinkler system. In another example best shown in FIG. 7, washing 16 may occur in a batch reactor 64 or a fluidized bed reactor.

In one embodiment represented generally in FIG. 2, the washing solution 18 may be acidic and may have an acid concentration of from 0.01 mol/L to 5 mol/L. For example, the washing solution 18 may have an acid concentration of 0.05 mol/L or 0.1 mol/L or 0.25 mol/L or 0.50 mol/L or 0.75 mol/L or 1 mol/L or 1.5 mol/L or 2 mol/L or 2.5 mol/L or 3.0 mol/L or 3.5 mol/L or 4.0 mol/L or 4.5 mol/L. For this embodiment, the washing solution 18 may include an acid selected from the group consisting of hydrofluoric acid, hydrochloric acid, acetic acid, nitric acid, sulfuric acid, phosphoric acid, and combinations thereof. In one specific example, the washing solution 18 may include hydrofluoric acid and the method 10 may include combining 22 the washing solution 18 and ammonium fluoride. Ammonium fluoride may serve as a buffer and may provide comparatively better control of etching speed and pH when the washing solution 18 includes hydrofluoric acid.

For the embodiment in which the washing solution 18 is acidic, the method 10 may also include contacting 20 the contaminant 12 with an oxidizer such as hydrogen peroxide and sparging 24 a gas 66 (as best shown in FIG. 7) through the washing solution 18. Suitable examples of gases may include oxygen gas, inert gases, functional gases such as oxidation gases and reduction gases, and combinations thereof. Such contacting 20 and sparging 24 ensures excellent dissolution of the contaminant 12 in the washing solution 18 and sufficient removal of the contaminant 12 from the optical component 14.

In another embodiment represented generally in FIG. 3, the washing solution 18 may be basic and may have an acid concentration of from 0.01 mol/L to 10 mol/L. For example, the washing solution 18 may have an acid concentration of 0.02 mol/L or 0.03 mol/L or 0.04 mol/L or 0.05 mol/L or 0.10 mol/L or 0.20 mol/L or 0.25 mol/L or 0.30 mol/L or 0.35 mol/L or 0.40 mol/L or 0.45 mol/L or 0.50 mol/L or 0.55 mol/L or 0.60 mol/L or 0.70 mol/L or 0.75 mol/L or 0.80 mol/L or 0.85 mol/L or 0.90 mol/L or 0.95 mol/L or 0.96 mol/L or 0.97 mol/L or 0.98 mol/L or 0.99 mol/L or 1 mol/L or 5 mol/L or 6 mol/L or 7 mol/L or 8 mol/L or 8.5 mol/L or 9 mol/L or 9.5 mol/L or 10 mol/L. For this embodiment, the washing solution 18 may include a base selected from the group consisting of ammonia, oxalate salts, and combinations thereof. In one specific example, the washing solution 18 may include an ammonia solution and oxalate salts and the method 10 may include combining 122 the washing solution 18 and lithium salt-containing anions.

For the embodiment in which the washing solution 18 is basic, the method 10 may also include contacting 20 the contaminant 12 with an oxidizer such as hydrogen peroxide and sparging 24 a gas 66 (as best shown in FIG. 7) through the washing solution 18. Suitable examples of gases may include oxygen gas, inert gases, functional gases such as oxidation gases and reduction gases, and combinations thereof. Such contacting 20 and sparging 24 may ensure excellent dissolution of the contaminant 12 in the washing solution 18 and sufficient removal of the contaminant 12 from the optical component 14.

In yet another embodiment represented generally in FIG. 4, the washing solution 18 may be organic. For this embodiment, the washing solution 18 may be selected from the group consisting of hydrazine, alcohols, ethers, amines, and combinations thereof. Further, the washing solution 18 may be a pure or mixed liquid. An organic washing solution 18 may provide for comparatively easy extraction and separation of the contaminant 12 from the lithium tantalate.

Referring now to FIGS. 1 and 5, the method 10 may also include, prior to washing 16, attaching 26 a mask 28 (FIG. 5) to the optical component 14 to cover an edge surface 30 (FIG. 5) of the lithium tantalate and expose at least a portion 32 (FIG. 5) of the contaminant 12. That is, the mask 28 may be disposed on an outer edge of the optical component 14 and may expose only the portion 32 of the contaminant 12. Stated differently, the mask 28 may protect the lithium tantalate from the washing solution 18 so that the washing solution 18 may not reach the lithium tantalate. For this embodiment, the washing solution 18 may include concentrated hydrochloric acid that may relatively slowly dissolve the contaminant 12, e.g., the lithium niobate, without affecting the lithium tantalate. That is, the method 10 may include dissolving 34 (FIG. 2) the contaminant 12 without dissolving the lithium tantalate.

For embodiments including the mask 28, the method 10 may also include, prior to washing 16, determining 36 (FIG. 2) a dissolution rate of the contaminant 12 at a plurality of temperatures. For example, the method 10 may include estimating the dissolution rate of lithium niobate at various temperatures using a blank lithium niobate sample. Then, once the dissolution rate of lithium niobate is determined, the contaminant 12 may be selectively removed from the lithium tantalate as set forth above based on the pre-determined dissolution rate.

Referring again to FIG. 1, the method 10 also includes forming 38 a compound 40 (FIG. 7) including the hard anion and the hard cation. That is, the hard anion of the washing solution 18 may target or bond with the hard cation of the contaminant 12. For example, for embodiments in which the contaminant 12 is lithium niobate and the washing solution 18 is hydrofluoric acid, the hard anion, F⁻, may target or bond with the hard cation, Li⁺, to form the compound 40, LiF. The compound 40 may be stable in the washing solution 18, may be a thermodynamically preferred metal-ligand complex product, and may be soluble in the washing solution 18. Similarly, the soft cation of the washing solution 18 may target or bond with the soft anion of the contaminant 12. That is, the soft cation, H⁺, may target or bond with the soft anion, NbO₃⁻, to form another compound (not shown), HNbO₃, which may also be soluble in the washing solution 18.

As described with continued reference to FIG. 1, the method 10 also includes rinsing 42 the compound 40 from the lithium tantalite to thereby selectively remove the contaminant 12 from the optical component 14. That is, the compound 40 and the other compound (not shown) may be rinsed away without disturbing, affecting, or changing the lithium tantalate.

Referring again to FIG. 6, the optical component 14 may be arranged as an elongated sheet 44 of material and the contaminant 12 may be shaped as a flat surface 46. For this embodiment, a recirculating sprinkler system may be effective for washing 16 the optical component 14 to remove the contaminant 12. For this embodiment, the method 10 may further include discharging 46 the washing solution 18 from at least one sprinkler component 50 disposed adjacent and facing the flat surface 46. The at least one sprinkler component 50 may be fixed in space and the elongated sheet may pivot and/or translate vertically and/or horizontally to ensure even washing 16.

After discharging 46, the method 10 may include collecting 52 the contaminant 12 in a leachate reservoir connected to the at least one sprinkler component 50 by a recirculation pump 54. As such, the washing solution 18 may be collected in the leachate reservoir 56 and recirculated to the sprinkler component 50 for reuse. For this embodiment, additional water cleaning may be possible without first transferring the optical component 14.

Referring now to FIG. 7, in another embodiment, the optical component 14 may be arranged as a plurality of chips 58 or may be a powder. The method 10 may further include submerging 60 the plurality of chips 58 in the washing solution 18 within a cavity 62 defined by a batch reactor 64. Further, the method 10 may include sparging 24 a fluid 66, e.g., a liquid, an inert gas, air, one or more oxidative gases, the washing solution, and combinations thereof, through the washing solution 18 within the cavity 62. After submerging 60, the method 10 may include suspending 68 the contaminant 12 in the washing solution 18. That is, since a density of lithium tantalate may be up to 60% higher than a density of the contaminant 12, e.g., lithium niobate, and since both lithium tantalate and the contaminant 12 are heavier than water, proper control of sparging flow from a bottom of the batch reactor 64 may allow the contaminant 12 to suspend in the washing solution 18 while the optical component 14 settles towards the bottom of the batch reactor 64. That is, the method 10 may include precipitating 70 the lithium tantalate away from the contaminant 12 within the cavity 62 to thereby remove the contaminant 12 from the optical component 14.

Physical Separation of the Contaminant 12 from the Optical Component 14

Referring now to FIG. 8, in another embodiment, the method 110 may include physically separating 72 the contaminant 12 from the optical component 14, as set forth in more detail below. Alternatively, the method 110 may include both chemically and physically separating 72 the contaminant 12 from the optical component 14.

With continued reference to FIG. 8, a method 110 of selectively removing the contaminant 12 from the optical component 14 formed from lithium tantalate includes maintaining 74 a thickness 76 (FIGS. 9-14) of the lithium tantalate, and physically separating 72 the contaminant 12 from the lithium tantalate to thereby selectively remove the contaminant 12 from the optical component 14. That is, maintaining 74 may include not disturbing or changing the lithium tantalate as the contaminant 12 is removed from the optical component 14.

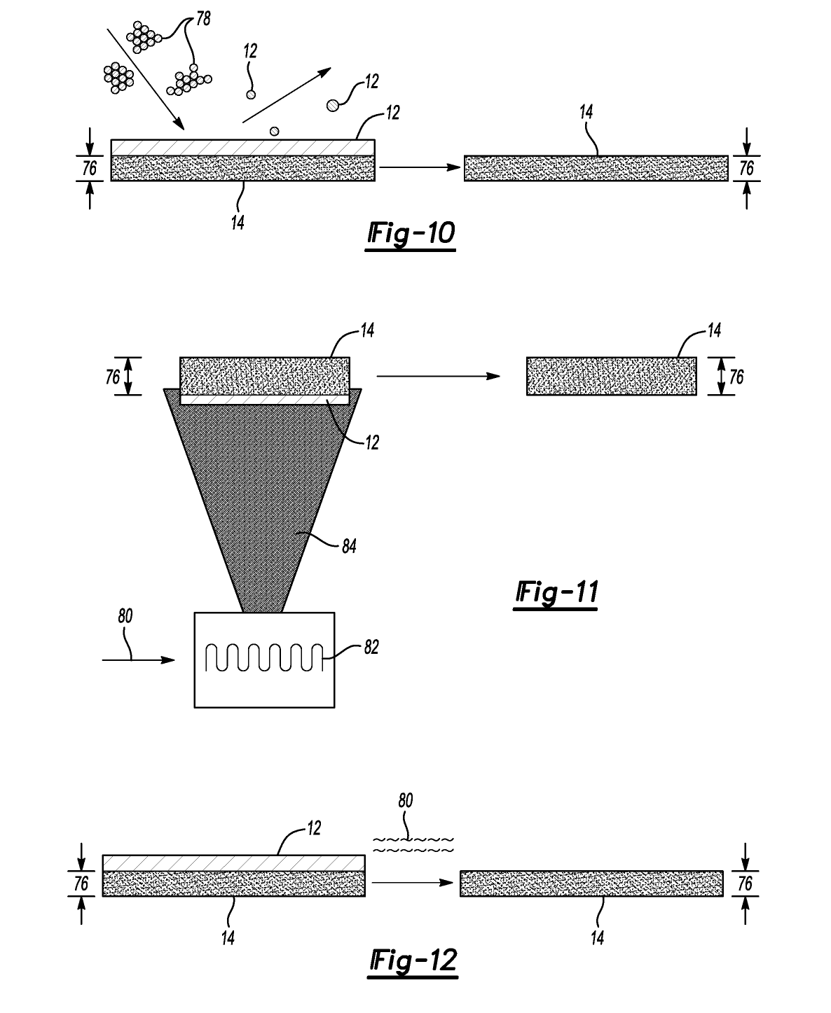

Referring to FIGS. 9 and 10, the optical component 14 may be arranged as the elongated sheet 44 or disc and the contaminant 12 may be shaped as the flat surface 46. For this embodiment, physically separating 72 may include at least one of monatomic ion beam sputtering and gas cluster ion beam sputtering an inert target material 78 at the contaminant 12.

With continued reference to FIG. 9, monatomic ion beam sputtering may eject ions from the inert target material 78 at the contaminant 12 and the ions may each consist of a single atom. Therefore, monatomic ion beam sputtering may achieve comparatively high yield sputter speed, may be a time- and power-controlled process, and may provide for controlled removal of the contaminant 12 from the lithium tantalate. Further, multiple samples of the inert target material 78, such as argon, may be used at once such that the monatomic ion beam sputtering is cost effective.

As shown in FIG. 10, for embodiments in which the contaminant 12 is relatively thin, a required roughness of the lithium tantalate is relatively high, and/or the lithium tantalate is comparatively thin and unable to be sacrificed, physically separating 72 may include gas cluster ion beam sputtering. That is, since even low energy monatomic ion beam sputtering may be unsuitable for thin optical components 14, physically separating 72 via gas cluster ion beam sputtering allows for relatively low energy consumption, lower operating speeds, and a comparatively smoother surface of the lithium tantalate upon removal of the contaminant 12. As compared to monatomic ion beam sputtering, gas cluster ion beam separating may eject a cluster of ions towards the contaminant 12.

Operating conditions such as sputter power or voltage, inert gas flow rate, a level of vacuum, a sputter rate, and a sputter time may be selected according to the initial physical characteristics, e.g., thickness 76, shape, and the like, of the contaminant 12 in addition to the desired smoothness of the finished optical component 14. For example, sputter time may be from 1 second to 5 hours. That is, sputter time may be 2 seconds or 4 seconds or 6 seconds or 8 seconds or 10 seconds or 30 seconds or 45 seconds or 1 minute or 10 minutes or 30 minutes or 1 hour or 1.5 hours or 2 hours or 2.5 hours or 3 hours or 3.5 hours or 4 hours or 4.5 hours or 5 hours. Further, the sputter rate may be calibrated for each optical component 14 by using a pure lithium niobate reference sample having a similar structure to the contaminant 12 or by using a lithium niobate-lithium tantalate reference sample having a known thickness. For the latter technique, a time until complete removal of lithium niobate may be noted as a reference.

In addition, physically separating 72 may include a combination of both monatomic ion beam sputtering and gas cluster ion beam sputtering. For example, the two techniques may be used sequentially. First, physically separating 72 may include fast removal of bulk lithium niobate via monatomic ion beam sputtering, followed by finishing a comparatively finer surface of lithium tantalate by removing the remaining contaminant 12 via gas cluster ion beam sputtering.

Alternatively, physically separating 72 may include C60 sputtering or liquid metal ion sputtering. Such techniques may also effectively physically separate the contaminant 12 from the lithium tantalate.

Referring now to FIG. 11, in another embodiment, physically separating 72 may include exposing the optical component 14 to a vacuum and plasma cleaning the contaminant 12 from the lithium tantalate. In addition to removing lithium niobate from the optical component 14, plasma cleaning may also be useful for removing organic material, e.g., long-chain carbon materials, from the optical component 14. Plasma cleaning may be performed in a vacuum chamber and may ionize a gas (represented generally at 80), such as air, argon, hydrogen, oxygen, nitrogen, and the like, across a filament 82 to form a plasma 84 which contacts the contaminant 12 and physically separates the contaminant 12 from the optical component 14.

Referring now to FIG. 12, in a further embodiment, physically separating 72 may include melting the contaminant 12 without melting the lithium tantalate. That is, the contaminant 12 and the lithium tantalate may have different melting points and/or densities. For example, lithium niobate may have a density of 4.65 g/cm³ and lithium tantalate may have a density of 7.46 g/cm³. Similarly, lithium niobate may have a melting point of 1,523.15 Kelvin and lithium tantalate may have a melting point of 1,898.15 Kelvin. As such, the method 110 may include heating and/or moving an inert gas 80 along the contaminant 12 to melt the contaminant 12 without melting the lithium tantalate. Since the contaminant 12 may melt before the lithium tantalate melts, the contaminant 12 may be physically removed from the lithium tantalate based on the comparatively lower density of the melted contaminant 12. Optionally, physically separating 72 may include gas purging to facilitate melting the contaminant 12 without melting the lithium tantalate.

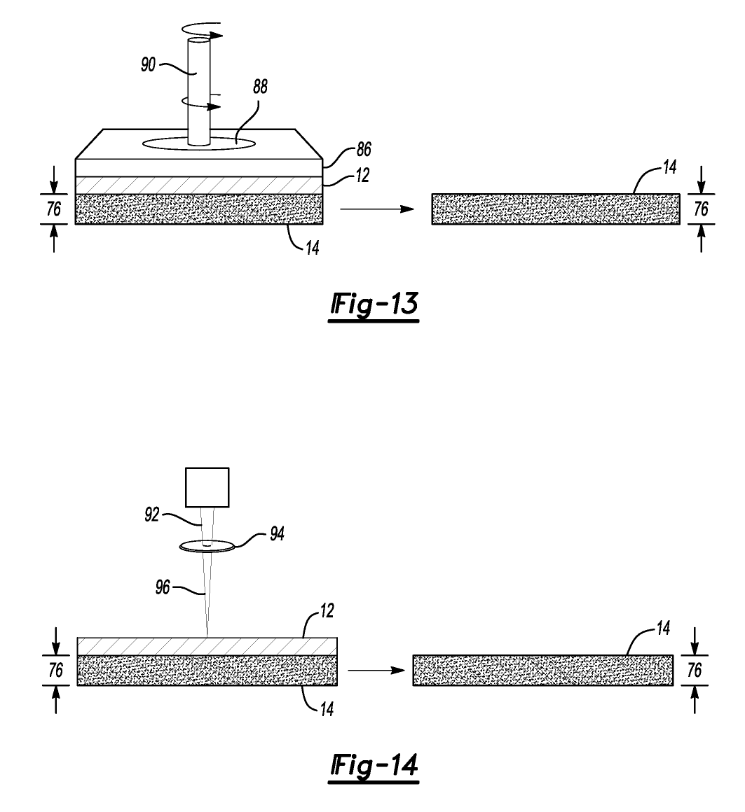

Referring now to FIG. 13, in another embodiment, physically separating 72 may include depositing a deagglomerated suspension 86 onto the contaminant 12 and polishing the contaminant 12 off the lithium tantalate with a polishing cloth 88. It is contemplated that this physical removal technique may be suitable for optical components 14 arranged as an elongated sheet 44 or disc. Suitable examples of the deagglomerated suspension 86 may be formed from a plurality of particles of diamond, alumina, silica, and the like, and the plurality of particles may have various sizes. Further, the polishing cloth 88 may be attached to a rotatable rod 90 or device and may be formed from, for example, rayon, silk, polyurethane, diamond, alumina, silica, and the like. In addition, the depositing and polishing may be combined with any of the techniques set forth above for chemically separating the contaminant 12 and the lithium tantalate. For this physical technique, a blank sample of the contaminant 12 of known thickness may be useful for calibrating the polishing and/or to calculate a polishing duration required to remove the contaminant 12 from the optical component 14.

Referring to FIG. 14, in another embodiment, physically separating 72 may include laser ablating the contaminant 12 to evaporate the contaminant 12 off the lithium tantalate. The method 110 may include laser ablating the contaminant 12 with, for example, a neodymium-doped yttrium aluminum garnet laser; a gas laser such as helium and helium-neon lasers; excimer lasers; dye lasers; semiconductor lasers; continuous wave lasers; pulsed wave lasers; and the like. Regardless of type, the laser 92 may be focused through a lens 94 to produce a beam 96 configured for ablating the contaminant 12. The energy of the laser 92 may melt or vaporize the contaminant 12 without melting the lithium tantalate such that the contaminant 12 may be removed from the optical component 14 without disturbing the lithium tantalate. Further, laser ablating may be especially suitable for optical components 14 or contaminants 12 having non-smooth geometries since the beam 96 may be configured to translate along peaks, valleys, and crevices of the contaminant 12.

Therefore, the methods 10, 110 are economical and efficient, provide chemical and/or physical techniques for removing contaminants 12, and augment optical component manufacturing processes to provide optical components 14 that are free from contaminants 12 and sacrificial residues. As such, the methods 10, 110 and optical components 14 may be suitable for use in LIDAR applications such as, but not limited to, autonomous and semi-autonomous vehicles.

While the best modes for carrying out the disclosure have been described in detail, those familiar with the art to which this disclosure relates will recognize various alternative designs and embodiments for practicing the disclosure within the scope of the appended claims.

What is claimed is:

1. A method of selectively removing a contaminant from an optical component formed from lithium tantalate, the method comprising:
washing the optical component with a washing solution that includes a hard anion;
wherein the contaminant includes a hard cation;
forming a compound including the hard anion and the hard cation; and
rinsing the compound from the lithium tantalate to thereby selectively remove the contaminant from the optical component.

2. The method of claim 1, wherein washing includes contacting the contaminant with the washing solution for from 5 minutes to 48 hours at a temperature of from 0 Kelvin to 493 Kelvin.

3. The method of claim 1, further comprising contacting the contaminant with an oxidizer;
wherein the washing solution is acidic and has an acid concentration of from 0.01 mol/L to 5 mol/L.

4. The method of claim 1, further comprising sparging a gas through the washing solution.

5. The method of claim 1, wherein the contaminant is lithium niobate and further wherein the washing solution includes an acid selected from the group consisting of hydrofluoric acid, hydrochloric acid, acetic acid, nitric acid, sulfuric acid, phosphoric acid, and combinations thereof.

6. The method of claim 1, wherein the washing solution includes hydrofluoric acid; and further comprising combining the washing solution and ammonium fluoride.

7. The method of claim 1, further comprising contacting the contaminant with an oxidizer;
wherein the washing solution is basic and has an acid concentration of from 0.01 mol/L to 10 mol/L.

8. The method of claim 1, wherein the contaminant is lithium niobate and further wherein the washing solution includes a base selected from the group consisting of ammonia, oxalate salts, and combinations thereof.

9. The method of claim 1, wherein the washing solution is selected from the group consisting of hydrazine, alcohols, ethers, amines, and combinations thereof.

10. The method of claim 1, further comprising, prior to washing, attaching a mask to the optical component to cover an edge surface of the lithium tantalate and expose at least a portion of the contaminant.

11. The method of claim 10, wherein the washing solution includes hydrochloric acid; and further comprising dissolving the contaminant without dissolving the lithium tantalate.

12. The method of claim 10, further comprising, prior to washing, determining a dissolution rate of the contaminant at a plurality of temperatures.

13. The method of claim 1, wherein the optical component is arranged as an elongated sheet and the contaminant is shaped as a flat surface, and further comprising:
discharging the washing solution from at least one sprinkler component disposed adjacent and facing the flat surface; and
after discharging, collecting the contaminant in a leachate reservoir connected to the at least one sprinkler component by a recirculation pump.

14. The method of claim 1, wherein the optical component is arranged as a plurality of chips, and further comprising:
submerging the plurality of chips in the washing solution within a cavity defined by a batch reactor;
sparging a fluid through the washing solution within the cavity;
after submerging, suspending the contaminant in the washing solution; and
precipitating the lithium tantalate away from the contaminant within the cavity.

15. A method of selectively removing a contaminant from an optical component formed from lithium tantalate, the method comprising:
maintaining a thickness of the lithium tantalate; and
physically separating the contaminant from the lithium tantalate to thereby selectively remove the contaminant from the optical component.

16. The method of claim 15, wherein the optical component is arranged as an elongated sheet and the contaminant is shaped as a flat surface; and wherein physically separating includes at least one of monatomic ion beam sputtering and gas cluster ion beam sputtering an inert target material at the contaminant.

17. The method of claim 15, wherein physically separating includes exposing the optical component to a vacuum and plasma cleaning the contaminant from the lithium tantalate.

18. The method of claim 15, wherein physically separating includes melting the contaminant without melting the lithium tantalate.

19. The method of claim 15,
wherein physically separating includes:
depositing a deagglomerated suspension onto the contaminant; and
polishing the contaminant off the lithium tantalate with a polishing cloth; and
wherein maintaining includes not disturbing the lithium tantalate.

20. The method of claim 15,
wherein physically separating includes laser ablating the contaminant to evaporate the contaminant off the lithium tantalate; and
wherein maintaining includes not disturbing the lithium tantalate.
